(19) United States
(12) Patent Application Publication
(10) Pub. No.: US 2021/0265954 A1
(43) Pub. Date: Aug. 26, 2021

(54) AN ARRANGEMENT FOR CATV AMPLIFIER CONTROL

(71) Applicant: Teleste Oyj, Littoinen (FI)

(72) Inventor: Toni RUMPUNEN, Raisio (FI)

(73) Assignee: Teleste Oyj, Littoinen (FI)

(21) Appl. No.: 17/253,332

(22) PCT Filed: Jun. 27, 2018
(86) PCT No.: PCT/FI2018/050510

§ 371 Date: Dec. 17, 2020

(51) Int. Cl. H03F 1/02; H04N 7/10; H04N 7/22; H04L 1/20; H04B 10/077; H04B 10/2575

(52) U.S. Cl. CPC H03F 1/0266; H04N 7/102; H04N 7/22; H03F 2200/63; H04B 10/0777; H04B 10/25751; H04L 1/203

(57) ABSTRACT

A network element of a cable television (CATV) network, said network element comprising one or more amplifier units for amplifying downstream signal transmission for digital output into one or more output channels; means for detecting modulation error ratio (MER) of all active digital output channels; and means for reducing bias current of said one or more amplifier units from a predetermined value until the MER value reaches a predetermined minimum value.

### FIELD OF THE INVENTION

The invention relates to cable television (CATV) networks, and especially to controlling CATV amplifiers.

### BACKGROUND OF THE INVENTION

CATV networks may be implemented with various techniques and network topologies, but currently most cable television networks are implemented as so-called HFC networks (Hybrid Fiber Coax), i.e. as combinations of a fiber network and a coaxial cable network. FIG. 1 shows the general structure of a typical HFC network. Program services are introduced from the main amplifier 100 (a so-called headend) of the network via an optical fiber network 102 to an optical node 104, which converts the optical signal to an electric signal to be relayed further in a coaxial cable network 106. Depending on the length, branching, topology, etc. of the coaxial cable network, this coaxial cable segment typically comprises one or more broadband amplifiers 108, 110 for amplifying program service signals in a heavily attenuating coaxial media. From the amplifier the program service signals are introduced to a cable network 112 of a smaller area, such as a distribution network of an apartment building, which are typically implemented as coaxial tree or star networks comprising signal splitters for distributing the program service signals to each customer. From a wall outlet the signal is further relayed either via a cable modem 114 to a television receiver 116 or a computer 118, or via a so-called set-top box 120 to a television receiver 122.

Both the optical nodes and amplifiers along the downstream path comprise a plurality of amplifier units/stages for amplifying the downstream signals. The parameters of the components in the amplifier stages within the network elements need to be dimensioned such they can handle the worst-case situation of the whole frequency area being loaded with active channels at maximum output level. On the other hand, in typical real-life use-cases there are a number of unallocated channels in the network and/or the output power level is not even close to maximum. This would allow running the RF amplifier components with smaller bias current to reach the needed RF performance level and thus lowering the power consumption of the device.

There are some traditional analogue amplifiers provided with automatic bias current control, where the output power after the last amplifier stage is measured and tuning the bias current is controlled based on the measured output power. However, the mere output power of RF signals is rather inaccurate in a sense that it provides limited amount of information about the underlying channel configuration. In practice, for adjusting the bias current of an amplifier in analogue channels, the exact channel raster offers better basis for amplifier component bias control.

### BRIEF SUMMARY OF THE INVENTION

Now, an improved arrangement has been developed to reduce the above-mentioned problems. As aspects of the invention, we present a network element of a cable television network, which is characterized in what will be presented in the independent claims.

The dependent claims disclose advantageous embodiments of the invention.

According to an aspect of the invention, there is provided a network element of a cable television (CATV) network, the network element comprising one or more amplifier units for amplifying downstream signal transmission for digital output into one or more output channels; means for obtaining modulation error ratio (MER) of all active digital output channels; and means for reducing bias current of said one or more amplifier units from a predetermined value until the MER value reaches a predetermined minimum value.

According to an embodiment, said bias current of said one or more amplifier units is arranged to be reduced stepwise and the MER values are arranged to be obtained at each step.

According to an embodiment, the predetermined minimum value of the MER corresponds to a maximum allowable value of MER.

According to an embodiment, the network element further comprises means for detecting the value of MER of said one or more active digital output channels.

According to an embodiment, the network element further comprises means for receiving a measured value of MER of said one or more active digital output channels from one or more cable modems connected to a network segment including said network element.

According to an embodiment, the network element further comprises means for implementing an algorithm to determine a control value, based on MER values from a plurality of cable modems, for adjusting the bias current.

According to an embodiment, the network element further comprises means for detecting bit error rate (BER) of all active digital output channels, wherein said means for reducing the bias current of said one or more amplifier units is arranged to stop reducing the bias current if a maximum allowable value of BER is reached.

According to an embodiment, the digital output channels are modulated according to Single-Carrier Quadrature Amplitude Modulation (SC-QAM) or Orthogonal Frequency-Division Multiplexing (OFDM).

According to an embodiment, said amplifier units comprise one or more of the following: a mid-stage amplifier unit, a gain control amplifier unit, a slope control amplifier unit, an output hybrid amplifier unit.

These and other aspects, embodiments and advantages will be presented later in the detailed description of the invention.

### BRIEF DESCRIPTION OF THE DRAWINGS

The invention will now be described in more detail in connection with preferred embodiments with reference to the appended drawings, in which:

FIG. 1 shows the general structure of a typical HFC network; and

FIG. 2 shows a simplified block chart of a network element according to an embodiment of the invention.

### DETAILED DESCRIPTION OF THE EMBODIMENTS

Data Over Cable Service Interface Specification (DOCSIS) is a CATV standard providing specifications for high-bandwidth data transfer in an existing CATV system. DOCSIS may be employed to provide Internet access over existing hybrid fiber-coaxial (HFC) infrastructure of cable television operators. DOCSIS has been evolved through versions 1.0, 1.1, 2.0 and 3.0 to the latest version of 3.1. DOCSIS provides a lucrative option for cable network providers to maximize both the downstream and upstream data throughput using the existing cable TV network, but without making expensive changes to the HFC network infrastructure.

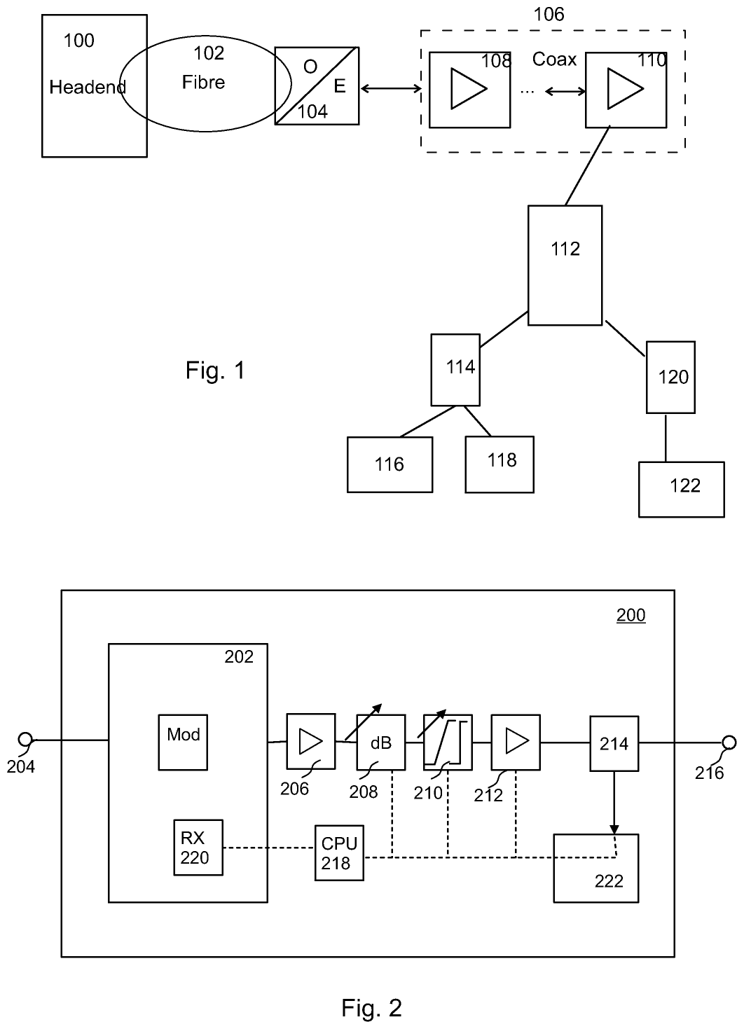

When implementing the HFC network of FIG. 1 according to DOCSIS, the headend 100 of the CATV network comprises inputs for signals, such as TV signals and IP signals, a television signal modulator and a cable modem termination system (CMTS). The CMTS provides high-speed data services to customers thorough cable modems (CM; 114) locating in homes. The CMTS forms the interface to the IP-based network over the Internet. It modulates the data from the Internet for downstream transmission to homes and receives the upstream data from homes. The CMTS additionally manages the load balancing, error correction parameters and the class of service (CoS).

Signals from the headend 100 are distributed optically (fiber network 102) to the vicinity of individual homes, where the optical signals are converted to electrical signals at the terminating points 104. The electrical signals are then distributed to the various homes via the existing 75 ohm coaxial cables 106. The maximum data transfer of the coaxial cables is limited due to strong frequency-based attenuation. Therefore, the electrical signals transmitted over coaxial cables must be amplified. The amplifiers 108, 110 used for this purpose are suited to a specific frequency range. In addition, the upstream and downstream must occur over the same physical connection. The last part 112 of the coaxial connection between the CMTS and the CMs branches off in a star or a tree structure. A CMTS transmits the same data to all CMs located along the same section of cable (one-to-many communications). A request/grant mechanism exists between the CMTS and the CMs, meaning that a CM needing to transmit data must first send a request to the CMTS, after which it can transmit at the time assigned to it.

Depending on the version of DOCSIS used in the CATV network, there is a great variety in options available for configuring the network. For the downstream channel width, all versions of DOCSIS earlier than 3.1 use either 6 MHz channels (e.g. North America) or 8 MHz channels (so-called “EuroDOCSIS”). However, the upstream channel width may vary between 200 kHz and 3.2 MHz (versions 1.0/1.1), and even to 6.4 MHz (version 2.0). 64-QAM or 256-QAM modulation is used for downstream data in all versions, but upstream data uses QPSK or 16-level QAM (16-QAM) for DOCSIS 1.x, while QPSK, 8-QAM, 16-QAM, 32-QAM, 64-QAM and 128-QAM are used for DOCSIS 2.0 & 3.0.

DOCSIS 3.1 specifications support capacities of at least 10 Gbit/s downstream and 1 Gbit/s upstream using 4096 QAM. DOCSIS 3.1 rejects the 6 or 8 MHz wide channel spacing and uses narrower orthogonal frequency-division multiplexing (OFDM) subcarriers being 20 kHz to 50 kHz wide, which sub-carriers can be combined within a block spectrum of about 200 MHz wide.

DOCSIS 3.1 further provides the concept of Distributed CCAP Architecture (DCA). Converged Cable Access Platform (CCAP) may be defined as an access-side networking element or set of elements that combines the functionality of a CMTS with that of an Edge QAM (i.e. the modulation), providing high-density services to cable subscribers. Conventionally, the CCAP functionalities have been implemented in the headend/hub, such as the headend 100 in FIG. 1. In a DCA, some features of the CCAP are distributed from headend/hub to the network elements closer to the customers, for example to the optical nodes 104 in FIG. 1. DOCSIS 3.1 specifies at least two network element concepts, i.e. a Remote PHY Device (RPD) and a Remote-MACPHY Device (RMD), to which some functionalities of the headend can be distributed. A recent version of DOCSIS 3.1 specification also provided Annex F introducing a Full Duplex DOCSIS 3.1 technology, where a new distributed access node called Full Duplex (FDX) Node is determined.

The data transmission between the distributed parts of the CCAP is typically carried out through a fiber connection. This may provide both scale advantages and flexible deployment options by maximizing the channel capacity and simplifying many operations via the usage of digital fiber and Ethernet transport.

The amplifiers and optical nodes in a HFC network (e.g. 104, 108, 110 in FIG. 1) are specified for some frequency range, today typically up to 1.2 GHz. The parameters of the components in the amplifier stages within the devices need to be dimensioned such they can handle the worst-case situation of the whole frequency area being loaded with active channels at maximum output level. On the other hand, in typical real-life use-cases there are a number of unallocated channels in the network and/or the output RF power level is not even close to maximum. This would allow running the amplifiers with smaller bias current and thus lowering the power consumption of the device.

In some existing optical node and amplifier products, there is a setting to lower the bias current for the output hybrid (i.e. the last amplifier stage before the output). Reducing the bias current decreases the performance of the output hybrid, but the output hybrid may be operated even with a partial load, if the reduction of the bias current is performed appropriately. Also, the bias current of the other amplifier stages may be reduced, even though the benefits in lowering the power consumption of the device are less obvious. This setting needs to be manually set in the user interface of the device. There are also traditional analogue devices with automatic bias current control, where the output power after the last amplifier stage is measured and tuning the bias current is controlled based on the measured output power. However, the mere output power of RF signals is rather inaccurate in a sense that it provides very little information about the underlying channel configuration. In practice, for adjusting the bias current of an amplifier in analogue channels, the exact channel raster needs to be known.

Consequently, an improved arrangement is presented herein for adjusting the bias current of amplifier units in network elements.

According to an aspect, a network element of a cable television (CATV) network is now introduced, said network element comprising one or more amplifier units for amplifying downstream signal transmission for digital output into one or more output channels; means for obtaining modulation error ratio (MER) of one or more active digital output channels; and means for reducing bias current of said one or more amplifier units from a predetermined value until the MER value reaches a predetermined maximum value.

Modulation error ratio (MER) indicates the deviations of the actual constellation points from the ideal locations caused e.g. by implementation imperfections or signal path. The modulation error ratio is equal to the ratio of the root mean square (RMS) power (in Watts) of the reference vector to the power (in Watts) of the error. It is defined in dB as: MER (dB)=10 log₁₀ (Pₑᵣᵣₒᵣ/P_{signal}), where Pₑᵣᵣₒᵣ is the RMS power of the error vector, and P_{signal} is the RMS power of ideal transmitted signal.

Thus, the smaller the value of MER (dB), the better is the signal quality. Vice versa, when the signal quality decreases, the MER value starts to grow until it reaches a level, which may still be considered “good enough”, i.e. still allowable.

Thus, starting from a predetermined bias current value, the value of MER of one or more active digital output channels is obtained. The first predetermined bias current value may be, for example, the maximum bias current value of the network element. If the detected MER value is “good enough”, i.e. still allowable, the bias current may be reduced and the value of MER corresponding to the reduced bias current is detected. This may be continued until the MER value reaches a predetermined maximum value. The bias current corresponding to the predetermined maximum value of MER is the minimum bias current value that may be used in order to achieve a still allowable signal quality.

According to an embodiment, said bias current of said one or more amplifier units is arranged to be reduced stepwise and the MER values are arranged to be obtained at each step. Thus, instead of continuously reducing the bias current, the bias current is reduced stepwise so as to obtain reliable measurements of MER at each bias current level.

According to an embodiment, the network element further comprises means for detecting the value of MER of said one or more active digital output channels. Said means for detecting the value of MER may comprise, for example, a transponder arranged to measure the MER at the output of the network element and to provide the MER value to means for reducing the bias current based on the MER value. Herein, for example a bias control circuitry may be used for evaluating the detected MER values such that the bias current is reduced, if the detected MER values are still allowable, i.e. below the predetermined maximum value.

Since the MER value is detected at the output of the network element, each network element may independently adjust its bias current values.

According to an embodiment, the network element further comprises means for receiving a measured value of MER of said one or more active digital output channels from one or more cable modems connected to a network segment including said network element. Thus, instead of or in addition to detecting the MER value at the output of the network element, the MER values may be received from cable modems connected to a CATV network segment underlying the network element.

Since the MER value is detected at one or more cable modems connected to the same network segment with the network element, the cable modems detect only the MER value in the output of the last network element in said segment. Thus, this embodiment enables to adjust the bias current values of the last network element of the network segment in downlink direction. On the other hand, measuring the MER values at the cable modems provide a more reliable result about the signal quality obtained by a customer than measuring the MER values at the output of the network element, since the signal quality is inevitably influenced by other network elements in the segment after transmitting it from the output of said network element.

However, the bias current values of any network element of the network segment in downlink direction may be adjusted according to the above embodiment, if the output power of the intermediate network elements (i.e. the network elements of the network segment in downlink direction between the network element in question and the cable modems) is known to be stable. For example, if the intermediate network elements are run at the maximum power, the network element in question may request the cable modems to send the MER values, adjust the bias current according to the received MER values and then request the cable modems to send new MER values to verify if the adjusted bias current value had any impact on the MER values detected by the cable modems.

According to an embodiment, the network element further comprises means for implementing an algorithm to determine a control value, based on MER values from a plurality of cable modems, for adjusting the bias current. Hence, if the MER values are obtained from a plurality of cable modems, an algorithm may preferably be implemented to determine a control value for adjusting the bias current. The control value may be determined, for example, according to the poorest (i.e. highest) MER value or as an average or a mean of the MER values obtained from the cable modems. It may also be determined as a weighted average of the MER values obtained from the cable modems, where the weights may correspond, for example, to the distance of each cable modem from the network element.

According to an embodiment, the predetermined maximum value of the MER corresponds to a maximum allowable value of MER.

Consequently, a predetermined maximum value of MER may be defined. Herein, the predetermined maximum value of MER may be defined, for example, as MER<−44 dB. If a lower signal quality is acceptable, the predetermined maximum value of MER may be defined, for example, as MER<−42 dB.

According to an embodiment, the network element further comprises means for detecting bit error rate (BER) of all active digital output channels, wherein said means for reducing the bias current of said one or more amplifier units is arranged to stop reducing the bias current if a maximum allowable value of BER is reached.

The bit error ratio (BER) is may be defined as the number of bit errors divided by the total number of transferred bits during a studied time interval. Thus, the smaller the value of BER, the better is the signal quality.

Consequently, in addition to MER, also a predetermined maximum value of BER may be defined. Herein, the predetermined maximum value of BER may be defined, for example, as BER<1*10e−10. If a lower signal quality is acceptable, the predetermined maximum value of BER may be defined, for example, as BER<1*10e−9.

A skilled person appreciates that the above MER and BER values are only mentioned as examples of appropriate values, and any other values that may be regarded as acceptable signal quality level may be used instead. It is further noted that maximum values of MER/BER need not necessarily be predetermined, but they may also be user-definable, for example in a case where manual adjustment is needed.

Hence, the MER measurement may be used as a primary indication for reducing the bias current. However, the BER measurement may be used as a secondary indication for reducing the bias current such that even if the MER value has not reached its predetermined maximum value, the reduction of bias current may still cause the BER value to increase to unallowable level. In such case, the BER measurement may be used to indicate that the bias current cannot be reduced anymore.

According to an embodiment, the digital output channels are modulated according to Single-Carrier Quadrature Amplitude Modulation (SC-QAM) or Orthogonal Frequency-Division Multiplexing (OFDM). Thus, the embodiments described herein are especially applicable to CATV system according to DVB-C and/or DOCSIS standards, such as DOCSIS 3.1.

FIG. 2 shows an example of a simplified block chart of network element according to an embodiment, the network element in this example being an optical node. FIG. 2 shows a simplification of the downstream path within the node; thus, no components relating to upstream path are shown. It is further noted that while FIG. 2 shows the implementation in a DCA device, such as an RPD/RMD node or an FDX node, the embodiments are equally applicable in any non-DCA node producing digital output signals.

The optical node 200 comprises a RPD/RMD module 202 arranged to receive digital downstream multiplexes from the headend via the optical interface 204. The RPD/RMD module 202 generates the RF output signals by modulating the digital signals accordingly. The network element typically comprises a plurality of amplifier units along the downstream path. There may be one or more mid-stage amplifier units 206, a gain control amplifier unit 208, a slope control amplifier unit 210 and the output hybrid amplifier unit 212.

According to an embodiment, a MER detector circuit 214 is arranged to detect the MER value of the one or more active digital output channels, which is supplied further to a network segment via an output node 216. The MER detector circuit 214 may also be provided with means for detecting the BER value of the active digital output channels.

The optical node 200, or the RPD/RMD module 202 therein, may comprise a processing unit (CPU) 218 for controlling the operation of at least some of components of the optical node. The optical node 200 may further comprise a receiver 220 for receiving a measured value of MER/BER of said one or more active digital output channels from one or more cable modems. If implemented in a DCA device, such as an RPD/RMD node or an FDX node, the receiver function 220 may be included in the RPD/RMD module 202. It is also possible that the MER/BER values of the cable modems are collectively gathered to a central storage with the CATV system, such as in a CMTS, and the CMTS sends the values to the network elements, for example upon request.

According to an embodiment, the processing unit 218 obtains the detected MER/BER values of the active digital output channels from the MER detector circuit 214. If the detected MER/BER values are still allowable, i.e. below their predetermined maximum value, the processing unit 218 controls a bias control circuitry 222 to reduce the bias current, preferably stepwise to a next level. The steps of detecting MER/BER values of the active digital output channels at the MER detector circuit 214 and controlling the bias control circuitry 222 to reduce the bias current is iteratively continued until the MER (or BER) value reaches a predetermined maximum value.

According to another embodiment, the processing unit 218 obtains the detected MER/BER values of the active digital output channels from one or more cable modems connected to the network segment with said network element. Thus, the receiver 220 receives the MER/BER values and provides them to the processing unit 218. If there are MER/BER values from a plurality of cable modems, the processing unit 218 may apply an algorithm to determine a suitable control value for adjusting the bias current. The control value may be determined, for example, as a (weighted) average or a mean of the MER/BER values. Then the processing unit 218 controls the bias control circuitry 222 to reduce the bias current similarly as described above.

As mentioned above, the embodiments are equally applicable in any non-DCA node producing digital output signals. Therefore, according to an embodiment, the bias control circuitry 222 may comprise means for evaluating the detected MER/BER values such that the bias control circuitry 222 reduces the bias current of one or more of these amplifier units, if the detected MER/BER values are still allowable, i.e. below their predetermined maximum value. Thus, the bias control circuitry 222 may carry out the iterative process of reducing the bias current until the MER (or BER) value reaches a predetermined maximum value, and no separate processing unit is needed.

In general, the various embodiments may be implemented in hardware or special purpose circuits or any combination thereof. While various embodiments may be illustrated and described as block diagrams or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

A skilled person appreciates that any of the embodiments described above may be implemented as a combination with one or more of the other embodiments, unless there is explicitly or implicitly stated that certain embodiments are only alternatives to each other.

The various embodiments can be implemented with the help of computer program code that resides in a memory and causes the relevant apparatuses to carry out the invention. Thus, the implementation may include a computer readable storage medium stored with code thereon for use by an apparatus, such as the network element, which when executed by a processor, causes the apparatus to perform the various embodiments or a subset of them. Additionally or alternatively, the implementation may include a computer program embodied on a non-transitory computer readable medium, the computer program comprising instructions causing, when executed on at least one processor, at least one apparatus to apparatus to perform the various embodiments or a subset of them. For example, an apparatus may comprise circuitry and electronics for handling, receiving and transmitting data, computer program code in a memory, and a processor that, when running the computer program code, causes the apparatus to carry out the features of an embodiment.

It will be obvious for a person skilled in the art that with technological developments, the basic idea of the invention can be implemented in a variety of ways. Thus, the invention and its embodiments are not limited to the above-described examples but they may vary within the scope of the claims.

1. A network element of a cable television (CATV) network, said network element comprising:
one or more amplifier units configured to amplify downstream signal transmission for digital output into one or more output channels;
a processing unit configured to obtain modulation error ratio (MER) of all active digital output channels:
a detector circuitry configured to detect circuitry configured to detect bit error rate (BER) of all active digital output channels; and
a control circuitry configured to reduce bias current of said one or more amplifier units from a predetermined value until the MER value reaches a predetermined maximum value or a maximum allowable value of BER is reached, wherein said bias current of said one or more amplifier units is arranged to be reduced stepwise and the MER and the BER values are arranged to be obtained at each step.

2. (canceled)

3. The network element according to claim 1, wherein the predetermined maximum value of the MER corresponds to a maximum allowable value of MER.

4. The network element according to claim 1, wherein said detector circuitry is further configured to detect the value of MER of said one or more active digital output channels.

5. The network element according to claim 1, further comprising a receiver configured to receive a measured value of MER of said one or more active digital output channels from one or more cable modems connected to a network segment including said network element.

6. The network element according to claim 5, wherein the processing unit is configured to implement an algorithm to determine a control value, based on MER values from a plurality of cable modems, for adjusting the bias current.

7. (canceled)

8. The network element according to claim 1, wherein the digital output channels are modulated according to Single-Carrier Quadrature Amplitude Modulation (SC-QAM) or Orthogonal Frequency-Division Multiplexing (OFDM).

9. The network element according to claim 1, wherein said amplifier units comprise one or more of the following: a mid-stage amplifier unit, a gain control amplifier unit, a slope control amplifier unit, an output hybrid amplifier unit.
